(19) United States
(12) Patent Application Publication
(10) Pub. No.: US 2008/0253087 A1
(43) Pub. Date: Oct. 16, 2008

(54) THERMAL MANAGEMENT SYSTEM FOR AN ELECTRONIC DEVICE

(75) Inventors: Gamal Refai-Ahmed, Markham (CA); Khalid Sheltami, Richmond (CA); Nima Osqueizadeh, Oak Ridges (CA)

Correspondence Address: ADVANCED MICRO DEVICES, INC.;C/O VEDDER PRICE P.C., 222 N.LASALLE STREET, CHICAGO, IL, 60601, US

(73) Assignee: ATI Technologies ULC, Markham (CA)

(21) Appl. No.: 11/733,586

(22) Filed: Apr. 10, 2007

(51) Int. Cl. H05K 7/20

(52) U.S. Cl. 361/695; 165/121

(57) ABSTRACT

A configurable multiple inlet thermal management device, such as an air-mover or passive heat sink, for electronic devices. The thermal management device is arranged on a computing device or on a component of a computing device or similar, such as an expansion module or alike, so that incoming air flow decreases the temperature of the heat producing components. In order to provide best possible air flow the air-mover comprises blade design that pressurizes the air flow from at least one side of the air-mover component. The air-mover includes removable covers for providing the openings required for intake air from the desired direction and for providing a fan wind. Depending on the application the openings may be permanently opened or closed. The intake air flow is then directed in form of fan wind towards the heat producing elements.

### FIELD OF THE INVENTION

The invention relates to thermal management in electronic devices.

### BACKGROUND OF THE INVENTION

Over the years computer graphics have advanced enormously. The resolutions have increased significantly and graphics production is improved with quality enhancement functionality. Similarly the customers have become more demanding in terms of quality of the graphics to be displayed. High quality graphics are needed in a plurality of different applications, such as in moving pictures, video clips, World Wide Web pages, gaming, user interfaces and so on. More resources are naturally needed also for producing this high quality content. Thus, graphics computing power is needed practically in every computing device.

In practice there are two ways of improving graphics computing power. The first one is the introduction of better algorithms and functionality and the second one is increasing computing power by increasing hardware computing capacity. This can be achieved by using faster processing units, increasing the number of processing units and using more memory on a board. It is common approach to work on both ways simultaneously so that the best possible result is achieved.

One problem in increasing the computing power by providing more and faster hardware components is the increased power consumption and heat generation. Even if new more power efficient hardware components are manufactured, it is likely that any possible saving in the power consumption due to increased efficiency will be used for producing higher quality graphics by using even more hardware.

Recently the demand in high quality graphics in certain applications has risen so much that it is very difficult or impossible to provide the demanded quality by using a single graphics device in a computer. The graphics devices are typically expansion cards that are installed on the main board of the computer or a work station. Typically there are several slots for installing additional cards on the main board. Thus, an obvious solution is to provide graphics devices that can cooperate with other graphics devices installed within the same computer. Dual installations have been known for several years and they provide an easy solution for the most demanding customers.

In a typical configuration two or more exactly similar graphics devices are installed to work in cooperative mode. As the cooperative mode is targeted to the most demanding users, it is common that the graphics cards used in the configuration are one of the most efficient ones. This means, that there are plurality of graphics devices with high power consumption and heat production. As the other components of the computer also produce heat, the ventilation of the computing device and the separate components within the device becomes extremely crucial.

Typically the most heat producing components in a computer, such as central processing and graphics processing units have their own fans for improved ventilation. Other solution is to equip heat producing components with passive thermal management systems that are capable of transferring the generated heat.

However, with similar devices this might be problematic as ventilation might be disturbed by the neighboring devices in both thermal management solutions. If the ventilation is disturbed the temperature of the device might rise above the operating temperature causing computation errors or stops in the operation of the device or otherwise force the device(s) to operate with lowered power consumption (typically resulting in lowered performance). In addition to graphics cards similar problems may be encountered also with other types of expansion cards. Thus, there is a need for improved ventilation for computing devices and particularly for graphics devices.

### SUMMARY

In an embodiment, the present invention discloses a thermal management device with configurable air intake in open environment. The present invention may be used with passive or active thermal management systems including fans and heat sinks. A thermal management device according to the present invention comprises adjustable intake air management, wherein the air flow is controlled by removable covers and/or by a special shroud configured to direct the intake to desired direction.

In an embodiment the thermal management device is a configurable multiple inlet air-mover component for electronic devices. The air-mover according to the present invention is arranged on a computing device or on a component of a computing device or similar, such as an expansion card or alike, so that incoming air flow decreases the temperature of the heat producing components. In order to provide best possible air flow the air-mover comprises blade design that pressurizes the air flow from at least one side of the air-mover component when the blades are moved by a motor. The air-mover includes removable covers for providing the openings required for intake air from the desired direction and for providing a fan generated air flow. Depending on the application the openings may be permanently opened or closed. The intake air flow is then directed in form of fan generated air flow towards the heat producing elements.

In an embodiment the air-mover further comprises a plurality of air flow exits having a removable cover for directing the air flow into desired direction.

In an embodiment the thermal management device further comprises a special shroud, which is configured to provide more configurable intake. The shroud is arranged on an air-mover, heat sink or a heat transferring element so that it takes the intake air flow from outside the possible impedance area. The shroud is configured to control the intake air flow direction of the heat transferring element, wherein said shroud is configured to block at least partially the air flow affected by air flow impedance caused by at leas one neighboring device. In an embodiment the shroud comprises coverable inlet openings.

The embodiments described above may be combined in order to produce thermal management devices to fulfill the different requirements of the different applications. For example, it is possible to combine both active and passive thermal management and equip the combination with special shroud having coverable openings.

A benefit of the invention is that it provides proper intake air flow towards the desired component without being disturbed or lessening the disturbance by air flow impedance generated by neighboring devices. This enables better air flow and thus better cooling. This is very important when dealing with small computing device case volumes hosting several heat producing elements.

A further benefit of the invention is that the desired component can be equipped with a standard heat sink. According to the conventional technology the heat sinks must be designed for ventilation systems and thus add complexity of the designing process.

### BRIEF DESCRIPTION OF THE DRAWINGS

The accompanying drawings, which are included to provide a further understanding of the invention and constitute a part of this specification, illustrate embodiments of the invention and together with the description help to explain the principles of the invention.

In the drawings:

FIG. 1a discloses three-dimensional illustrations of an embodiment according to the present invention,

FIG. 1b is an exploded view of the embodiment of FIG. 1a,

FIG. 1c is a further view of embodiment of FIGS. 1a and 1b,

FIG. 2 is a block diagram of an example embodiment of the present invention installed on a host device, and

FIG. 3 is a block diagram of an example embodiment of the present invention installed on a host device, wherein one of the thermal management devices is a passive heat sink comprising a shroud.

### DETAILED DESCRIPTION OF THE INVENTION

Reference will now be made in detail to the embodiments of the present invention, examples of which are illustrated in the accompanying drawings.

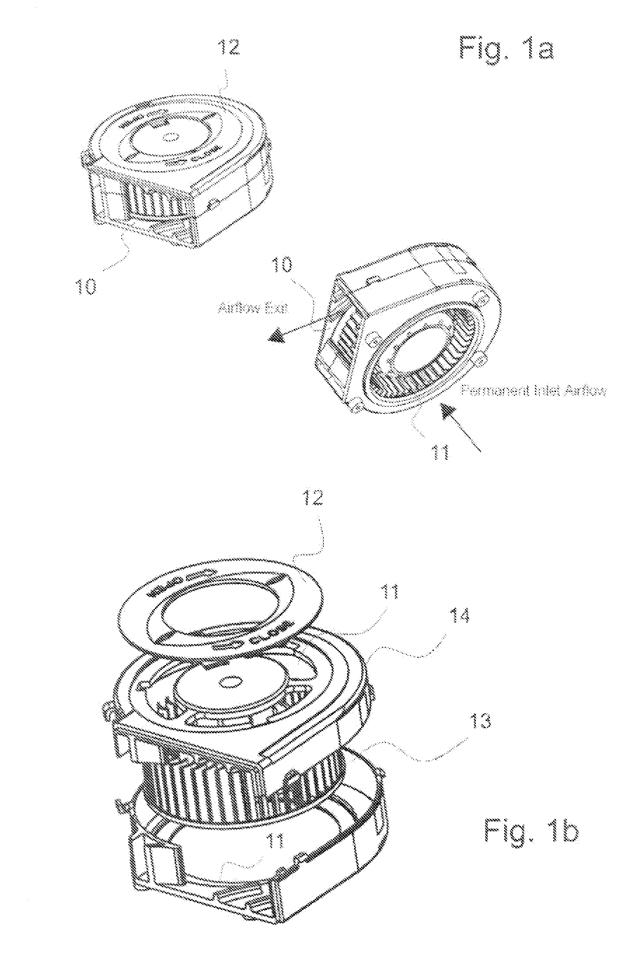

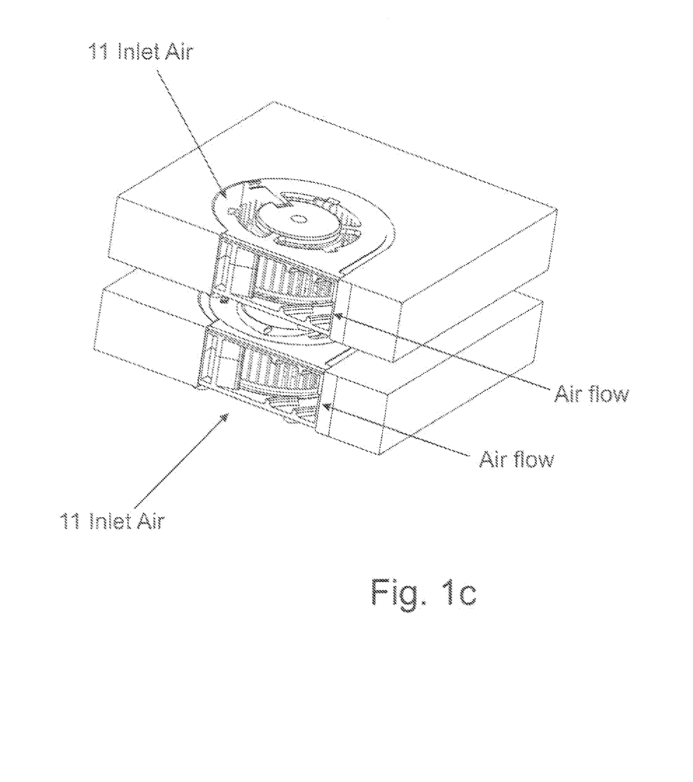

In FIG. 1a two different views of an air-mover according to the present invention are disclosed. The air-mover according to the present embodiment comprises an air flow exit 10, permanent inlet 11 for intake air flow and a removable cover 12 for the permanent inlet. The present embodiment includes similar permanent inlet also in the opposite side of the air-mover. The opposite inlet is visible in FIG. 1c. In other embodiments it is possible to make further openings if needed for improving ventilation. However, also these openings are provided with removable cover. The further openings may be provided for inlet or exit air flows.

FIG. 1b is an exploded view of the embodiment of FIG. 1a. The air-mover of FIG. 1b comprises air-moving mechanism including blades and a motor for providing air flow 13, housing 14 having permanent inlet openings 11 and a removable cover 12 for one of the openings. If the invention is implemented with more than two openings more covers are also needed if only one opening is kept uncovered. Removable cover 12 is advantageously attached to the cover by latches or other attachment mechanism. In one embodiment the cover employs a mechanism which allows a user of the device to forego the use of tools for attaching and detaching the cover. However, it is possible to use any known attaching means for the cover 12.

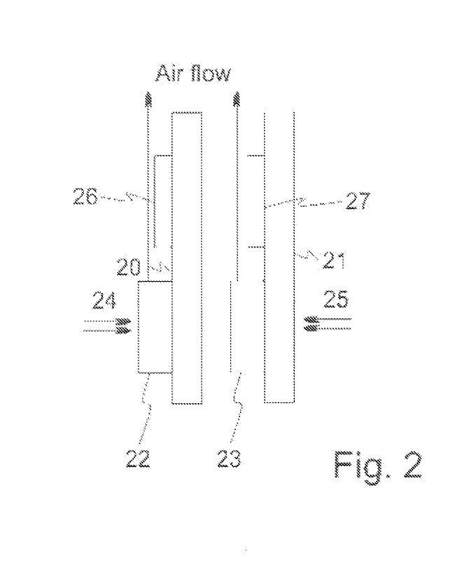

In FIG. 2 a block diagram of an example embodiment of the present invention is disclosed. In FIG. 2 two air-mover components are installed on expansion modules. In the embodiment of FIG. 2 the expansion modules are expansion modules 20 and 21 installed on a main board of the host computer. Expansion modules may be any expansion cards, modules or similar that can be attached to a computing device, such as a personal computer, work station or similar. For clarity reasons the main board of the host computer is not presented in the Figure. It is obvious to a person skilled in the art that the expansion modules and the main board are connected via an appropriate bus. The appropriate bus is typically implemented in form of expansion slots so that a plurality of expansion cards can be attached to the computing device. In FIG. 2 expansion modules 20 and 21 are illustrated and they are connected to the neighboring slots.

The expansion modules of FIG. 2 are equipped with air-movers 22 and 23, such as the air-mover disclosed in FIG. 1. The air-movers used in the embodiment of FIG. 2 have two permanent inlets. The inlets are configured so that in both of the air-movers the inlet next to the neighboring expansion module is covered and air flows 24 and 25 represent the inlet air flow in the present embodiment. Thus, the inlet air flows 24 and 25 are not disturbed by air flow impedance generated by the air-mover of the neighboring expansion module. In the embodiment of FIG. 2 the exit air flow is then directed to the heat generating components 26 and 27. An example of heat generating component is a processing unit of the expansion module. The heat generating components 26 and 27 may be equipped with heat sinks that are not presented. The embodiment of FIG. 2 thus efficiently provides an air flow towards the heat producing elements without being disturbed by air flow impedance.

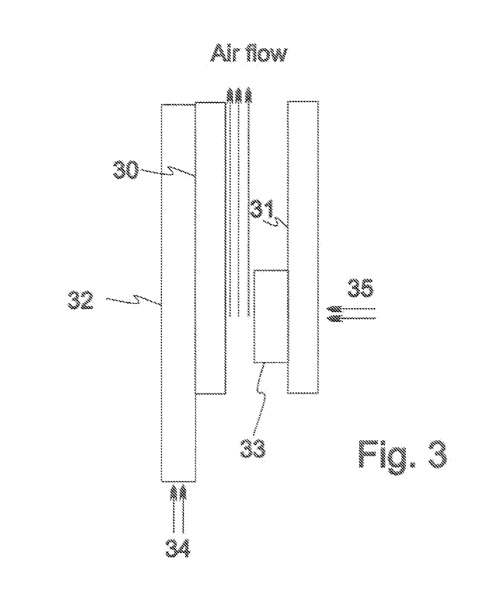

The embodiment of FIG. 3 differs from the embodiment of the FIG. 2 so that one of the modules has a shroud. Module 31 is similar to module 21 of FIG. 2, wherein the thermal management element 33 is an air-mover which directs the air flow 35 to the desired direction. Module 30 is equipped with a shroud 32. Under the shroud 32 there may be active or passive thermal management system. The purpose of the shroud is to direct the intake air flow 34 from a direction that would not be possible with the thermal management system similar to the air-mover 33 in the module 31.

As persons of ordinary skill in the art will appreciate, the invention herein can equally be applied to servers, computer systems, devices within racks or blade-type computing devices. For example, blade-type or style computing devices are well known to those skilled in the art. Multiple blade-type computing devices may be installed within a rack system in close proximity to one another. To improve air flow and decrease air movement impedance caused by conflicting air intake requirements caused by multiple blades proximate to each other, the invention could be applied to, for example, each of the blade-type computing devices. That is, the housing for the entire blade-type computing device may have two air inlets, an outlet (or exhaust) and an air moving mechanism such as a fan disposed within the computing device housing. An air inlets of two adjacent another blade-type computing device could each be closed (or partially closed) to reduce the air movement impendence. Alternatively and assuming the inlets for each of a plurality of blade-type server devices are on the top and bottom faces of each of the devices, the top surface air inlets for each of the computing devices could be closed (or partially closed or blocked) to reduce air impedance throughout the entire rack of computing devices.

It is obvious to a person skilled in the art that with the advancement of technology, the basic idea of the invention may be implemented in various ways. The invention and its embodiments are thus not limited to the examples described above; instead they may vary within the scope of the claims.

1. A thermal management device for electronic devices comprising:
a housing for housing an air moving device for producing an air flow, said housing comprising at least two inlet openings for incoming air and at least one opening for said produced air flow.

2. The thermal management device according to claim 1, wherein the device further comprises blades configured to move said blades for producing an air flow.

3. The thermal management device according to claim 1, wherein the device further comprises at least one cover for at least partially covering at least one of said at least two permanent inlet openings.

4. The thermal management device according to claim 3, wherein said cover is configured to block at least partially the inlet air flow from a direction having air flow impedance.

5. The thermal management device according to claim 1, wherein the device further comprises at least one cover for at least partially covering at least one permanent opening for said produced air flow.

6. The thermal management device according to claim 2, wherein the device further comprises a motor configured to move said blades.

7. A system comprising a thermal management device for providing an air flow, wherein in the thermal management device further comprises:
a housing for housing an air moving device for producing an air flow, said housing comprising at least two inlet openings for incoming air and at least one opening for said produced air flow.

8. The system according to claim 7, wherein the thermal management device further comprises blades configured to move said blades for producing an air flow.

9. The system according to claim 7, wherein the thermal management device further comprises at least one cover for at least partially covering at least one permanent inlet opening.

10. The system according to claim 9, wherein said cover is configured to block at least partially the inlet air flow from a direction having air flow impedance.

11. The system according to claim 7, wherein the system further comprises at least one cover for at least partially covering at least one permanent opening for said produced air flow.

12. A device for providing configurable intake air flow for thermal management comprising:
a heat transferring element; and
a shroud configured to control the intake air flow direction of said heat transferring element, wherein said shroud is configured to block at least partially the air flow affected by air flow impedance caused by at least one neighboring device.

13. The device according to claim 12, wherein said shroud comprises coverable inlet openings.

14. The device according to claim 12, wherein the heat transferring element is a passive heat sink.

15. The device according to claim 12, wherein the heat transferring element is an active air-mover with fan.

16. An expansion card for computing device comprising a device for providing configurable intake air flow for thermal management comprising:
a heat transferring element; and
a shroud configured to control the intake air flow direction of said heat transferring element, wherein said shroud is configured to block the air flow affected by air flow impedance caused by at leas one neighboring device.

17. The expansion card according to claim 16, wherein said shroud comprises coverable inlet openings.

18. The expansion card according to claim 16, wherein the heat transferring element is a passive heat sink.

19. The expansion card according to claim 16, wherein the heat transferring element is an active air-mover with fan.

20. A method for operating a computer system comprising at least two expansion modules, each of said modules having a thermal management device with an air inlet, said method comprising:
configuring an air inlet of at least one of said at least two expansion modules to reduce air flow impedance caused by another of said at least two expansion modules.

21. The method of claim 20 wherein said configuring comprises directing the air flow into said air inlet from a direction that reduces said air flow impedance.

22. The method of claim 20 wherein said configuring comprises at least partially covering said air inlet of said at least one of said at least two expansion modules.

23. The method of claim 22 wherein said covering comprises at least partially covering at least one air inlet on each of two expansion modules so as to reduce air flow impedance to each of said two expansion modules.
